(19) United States
(12) Patent Application Publication
(10) Pub. No.: US 2015/0287853 A1
(43) Pub. Date: Oct. 8, 2015

(54) METHOD FOR PRODUCING SEMICONDUCTOR FILM, SOLAR CELL, AND CHALCOPYRITE COMPOUND

(71) Applicant: Hitachi, Ltd., Chiyoda-ku, Tokyo (JP)

(72) Inventor: Tomoyuki Hamada, Tokyo (JP)

(21) Appl. No.: 14/436,886

(22) PCT Filed: Oct. 26, 2012
(86) PCT No.: PCT/JP2012/077675

§ 371 Date: Apr. 18, 2015

(51) Int. Cl. H01L 31/032; H01L 31/18

(52) U.S. Cl. CPC H01L 31/0322; H01L 31/18; H01L 31/1864

(57) ABSTRACT

To provide an optical absorption layer of a solar cell having the most pertinent optical band gap without using a highly toxic gas in repairing a Z atomic defect which is produced in a film after forming a chalcopyrite compound XYZ₂ thin film. The Z atomic defect is repaired by a sulfur atom by subjecting the chalcopyrite compound film XYZ₂ to an annealing treatment in a gas atmosphere including sulfur under a pressurized condition after forming the chalcopyrite compound film XYZ₂. A value of x+y in XYZₓS_{y} equal to or more than 0.95 and equal to or less than 2 by the annealing treatment.

### FIELD OF THE INVENTION

The present invention relates to a fabrication method of a semiconductor film, a solar cell and a chalcopyrite compound, particularly relates to a solar cell having high photoelectric conversion efficiency, a composition of an optical absorption layer thereof, and a fabrication method of a semiconductor film which is an optical absorption layer thereof.

### BACKGROUND OF THE INVENTION

FIG. 4 shows a representative configuration of a solar cell. The configuration is constructed by a structure in which a back electrode, an optical absorption layer, a buffer layer of ZnS or the like, and a transparent electrode are laminated above a substrate, and in recent years, attention is attracted to a solar cell using a chalcopyrite compound as an optical absorption layer.

The chalcopyrite compound is a compound semiconductor having a chemical formula XYZ₂ including a 1B group element X (X is Cu or Ag), a 3B group element Y (Y is Al, Ga, or In), and a 6B group element Z (Z is S, Se, or Te). The chalcopyrite compound shows an optical absorption characteristic which differs by a chemical composition, in the compound, CuInSe₂ shows optical absorption which is higher than that of silicon from infrared to ultraviolet wavelength region, and therefore, CuInSe₂ attracts attention as a material of a solar cell.

A number of technologies are known concerning a fabrication method of a chalcopyrite compound, and the technologies are grossly classified to: A. a technology concerning a fabrication of a chalcopyrite compound thin film; and B. a technology concerning a film treatment after fabricating the film.

As publicly known literatures concerning A. the technology of film fabrication, there are Japanese Unexamined Patent Application Publication No. Hei 9(1997)-213977 and Japanese Unexamined Patent Application Publication (Translation of PCT Application) No. 2007-503708. Japanese Unexamined Patent Application Publication No. Hei 9(1997)-213977 discloses a method of forming a CuInSe₂₋ₓSₓ thin film by controlling distributions of selenium and sulfur in a depth direction of the film, and giving a change in an optical band gap in the depth direction of the film. The literature shows that a solar cell having a high open voltage can be configured by using the CuInSe₂₋ₓSₓ thin film formed the method for an optical absorption layer. Japanese Unexamined Patent Application Publication (Translation of PCT Application) No. 2007-503708 discloses a method of fabricating a semiconductor thin film configured by a chalcopyrite compound 4 elements alloy or 5 or more elements alloy.

Japanese Unexamined Patent Application Publication No. Hei 9(1997)-213977 and Japanese Unexamined Patent Application Publication (Translation of PCT Application) No. 2007-503708 describe stoichiometric methods of fabricating a chalcopyrite compound thin films which do not include an atomic defect. However, as shown in Maeda, Wada, “CuInSe₂ no Denshi Kozo to Koshi Kekkan (Electronic Structure and Lattice Defect of CuInSe₂) ‘Recent Development of Thin Film Compound Semiconductor Photovoltaic Cells’”, CMC Publishing CO., LTD. Tokyo (2007), pp. 18-28, a stoichiometric chalcopyrite compound is more unstable than a non-stoichiometric chalcopyrite compound including a Z atomic defect. Therefore, in the methods of carrying out high temperature treatments at 500° C. or higher which are described in Japanese Unexamined Patent Application Publication No. Hei 9(1997)-213977 and Japanese Unexamined Patent Application Publication (Translation of PCT Application) No. 2007-503708, the Z atomic defect is caused in the film after forming the film, and the stoichiometric chalcopyrite compound thin film as asserted by these structures is not obtained.

The Z atomic defect of the thin film in the chalcopyrite compound is operated as a recombination center of an electron and a hole. Therefore, it is preferable to repair the Z atomic defect in the film in order to obtain the chalcopyrite compound thin film having high photoelectric conversion efficiency.

B. The film treatment after forming the film is a technology for resolving the problem. There are Japanese Unexamined Patent Application Publication No. Hei 6(1994)-120545 and Japanese Unexamined Patent Application Publication No. 2012-15328 as publicly known literatures concerning the technology B. Japanese Unexamined Patent Application Publication No. Hei 6(1994)-120545 describes a method of repairing a selenium atomic defect in a film by annealing a thin film of CuInSe₂ after a film fabricating process at a treatment temperature equal to or higher than 250° C. and equal to or lower than 550° C. under a hydrogen selenide (H₂Se) gas atmosphere. Also, the literature describes that when the annealing process is carried out not under the H₂Se atmosphere but under a hydrogen sulfide (H₂S) gas atmosphere, a sulfur atom is brought into the selenium atomic defect in the film, and an optical band gap only at a film surface can also be changed.

Japanese Unexamined Patent Application Publication No. 2012-15328 describes a method of repairing a generated selenium atomic defect by diffusing a selenium atom in the film while reducing selenium atomic defect formation which is caused after forming the film by rapidly cooling the CuInSe₂ film as crystallized down to 210° C. or lower and carrying out a selenium (Se) gas annealing.

### SUMMARY OF THE INVENTION

Japanese Unexamined Patent Application Publication No. Hei 6(1994)-120545 and Japanese Unexamined Patent Application Publication No. 2012-15328 describe the methods of repairing the Z atomic defect caused in the film after forming the chalcopyrite compound thin film including selenium as Z by the annealing treatment under the H₂Se or Se gas atmosphere. However, there poses a problem that H₂Se and Se gas are toxic.

Although the method of Japanese Unexamined Patent Application Publication No. Hei 6(1994)-120545 using the H₂S gas having less toxicity is worth paying attention, the repairing of the selenium atomic defect of the CuInSe₂ film by H₂S gas is limited to the surface of the film. This method aims to achieve high conversion efficiency by changing an optical band gap only at the surface of the film.

It is the object of the present invention to provide an optical absorption layer having the most pertinent optical band gap without using a gas having high toxicity in repairing a Z atomic defect caused in a film after forming a chalcopyrite compound thin film represented by CuInSe₂.

First, an explanation will be given of a fabrication method.

(1) The object described above is achieved by subjecting a chalcopyrite compound film to an annealing treatment in a gas atmosphere including sulfur under a pressurized condition after forming the film.

A representative example of the chalcopyrite compound having a chemical formula of XYZ₂, in which X is silver or copper, Y is gallium, indium, or aluminum, Z is sulfur, selenium, or a tellurium. The chalcopyrite compound may be configured not only by a ternary system, but a four or more elements system having two kinds of elements as Y.

Here, in comparison with a background art, in Japanese Unexamined Patent Application Publication No. Hei 6(1994)-120545, in a case of using H₂S gas having less toxicity, only the Z atomic defect at a surface of the film is repaired by a sulfur atom. The fact shows that in Japanese Unexamined Patent Application Publication No. Hei 6(1994)-120545, only a Z atomic defect near to a surface of a crystal is repaired and the Z atomic defect existed at the inner portion of the crystal cannot be repaired. According to the method, since only the film surface is repaired, an annealing time period is believed to be about several seconds.

On the other hand, the present invention allows the Z atomic defect over a total of the film to be repaired by a sulfur atom by diffusing sulfur to an inner portion of a crystal by annealing a chalcopyrite thin film in a gas atmosphere including sulfur under a pressurized condition.

When a polycrystal chalcopyrite thin film is annealed by using a pressurized sulfur gas, in comparison with a case of no pressurization, more sulfur atoms per time can be supplied to a surface of a crystal grain of chalcopyrite configuring a thin film, and the Z atomic defect which exists at an inner portion of the crystal grain which cannot be treated in the case of no crystallization can be repaired by a sulfur atom by accelerating to diffuse the sulfur atom to the inner portion of the crystal grain. Specifically, in a case of using a sulfur gas at 10 atm, in comparison with a case of 1 atm, an amount of sulfur atoms supplied per unit time to a unit surface of the crystal grain can be made to be 10 times as much as that in the case of 1 atm.

Incidentally, the reason of repairing only the surface of film in Japanese Unexamined Patent Application Publication No. Hei 6(1994)-120545 is as follows. First, an output voltage can be increased. A P/N junction of a CuInSe₂ solar cell exists at a surface of CuInSe₂ on a side on which a solar ray is incident. When S is introduced to the surface, an optical band gap at the junction can be increased, and an output can be increased by increasing an output voltage. Successively, efficiency of taking out a carrier is increased. When an optical band gap at a vicinity of the surface is increased by introducing S to the surface, a gradient can be attached to the optical band gap. When the gradient is attached to the optical band gap, a carrier (electron and hole) by optical absorption can efficiently be taken out to outside. As a result, an output is increased by increasing a current. In this way, it is an object of Japanese Unexamined Patent Application Publication No. Hei 6(1994)-120545 to attach a gradient to an optical band gap by only repairing a surface of the film, which is quite different from a configuration in which a Z atom defect over a total of the film is repaired by a sulfur atom to provide an optical absorption layer having the most pertinent optical band gap as in the present application.

(2) A temperature of the annealing treatment is made to be lower than a melting point (217° C.) of selenium and higher than a melting point (112° C.) of sulfur in a case where Z=Se or S.

It is preferable that the annealing treatment temperature of the chalcopyrite compound after forming the film is made to be as low as possible from a view point of restraining a detachment of the Z atom from the film and reducing as much as possible the Z atomic defect in the film. On the other hand, when the film treatment temperature is lower than the melting point of Z, Z aggregates in the film, a chemical composition of the film is in excess of Z, which is not preferable.

Hence, the detachment of the Z atom is restrained as much as possible and at the same time the sulfur atom is prevented from aggregating in the film excessively by making the treatment temperature of the film lower that in the background art technology by making the treatment temperature of the chalcopyrite compound including selenium or sulfur as Z lower than the melting point (217° C.) of selenium and higher than the melting point (112° C.) of sulfur.

According to the methods of Japanese Unexamined Patent Application Publication No. Hei 6(1994)-120545 and Japanese Unexamined Patent Application Publication No. 2012-15328 using H₂Se or Se gas, the treatment temperature of the film cannot be made to be lower than the melting point of selenium in order to prevent the aggregation of selenium into the film. In contrast thereto, according to the method of the present invention using a gas including S of H₂S or the like, the treatment temperature of the film can be made to be lower than the melting point of selenium.

As a result, the detachment of selenium from inside of the film can substantially be restrained in a case of treating the chalcopyrite compound thin film having selenium as Z by the present invention.

(3) A temperature in the annealing treatment described above is made to be lower than the melting point (449° C.) of tellurium and higher than the melting point (112° C.) of sulfur in a case of Z=Te. Thereby, the detachment of the tellurium atom from the film is restrained as much as possible, and at the same time, the sulfur atom is prevented from aggregating into the film excessively.

According to the background art using hydrogen telluride (H₂Te), the treatment temperature of the film cannot be made to be lower than the melting point of tellurium, in order to prevent aggregation of tellurium into the film. In contrast thereto, according to the method of the present invention using a gas including S of H₂S or the like, the treatment temperature of the film can be made to be lower than the melting point of tellurium, and the detachment of the tellurium from inside of the film can be restrained.

(4) The annealing treatment is made to be carried out by making the pressure of the gas including S as from 2 atm to 100 atm. Thereby, the Z atomic defect of the polycrystal chalcopyrite thin film having the film thickness becomes able to be repaired by the sulfur atom.

It is preferable that the pressure of the gas including S is high from a view point of repairing the Z atom in the chalcopyrite compound thin film, and therefore, it is preferable that the pressure of the gas is equal to or higher than 10 atm. On the other hand, the higher the pressure of the gas, the more complicated the device for the treatment, and therefore, it is preferable for mass production to repair the Z atom in the chalcopyrite thin film by using the gas including S at a comparatively low pressure.

(5) H₂S is preferable as the gas including sulfur. A molecular weight of H₂S gas is the smallest as the molecule including sulfur, and H₂S gas is excellent in diffusivity, and suitable for the annealing treatment of the polycrystal chalcopyrite compound thin film. Further, a product in a case where H₂S is decomposed at the surface of the chalcopyrite compound is only H₂ which is detached easily from the surface and S which is necessary for repairing the Z atom defect, and H₂S has an advantage in which a chemical residue of contaminating the surface is not produced.

Successively, an explanation will be given of the chalcopyrite compound film.

(6) A chalcopyrite compound is made to have a chemical composition of XYSeₓS_{y} or XYTeₓS_{y}, where a value of x+y is equal to or more than 1.95 and equal to or less than 2. Here, X is silver or copper, Y is gallium, indium, or aluminum, Z is sulfur, selenium or tellurium.

According to Japanese Unexamined Patent Application Publication No. Hei 6(1994)-120545 and Japanese Unexamined Patent Application Publication No. 2012-15328, the defect over the total of the film cannot be repaired, and therefore, x+y is believed to be equal to or less than 1.90. On the other hand, according to the present application, the defect of the total of the film is repaired, and therefore, a value of x+y is equal to or more than 1.95 and equal to or less than 2.

Explaining in details by using a specific example, when an annealing treatment of a thin film of a chalcopyrite compound XYSeₓV_{z} having a selenium atom and a selenium atomic defect V is carried out, a sulfur atom is introduced to V, and a thin film having a chemical composition of XYSeₓS_{y}V_{z-y} is obtained. Here, y≦z and 1.95<x+y<x+z=2.

As in (1) described above, when the polycrystal CuInSeₓ thin film is treated, the sulfur atom is introduced into the selenium atomic defect in the film, and the chalcopyrite compound thin film having the chemical composition of CuInSeₓS_{y} is obtained. A range of x+y is equal to or more than 1.95 and equal to or less than 2, and in comparison with the case where the treatment is not carried out, the Z atomic defect density in the film can be lowered. Thus, the CuInSe₂ film having less carrier recombination by the Z atomic defect can be obtained.

Further, the CuInSeₓS_{y} thin film obtained by the treatment has an optical band gap larger than that of the CuInSeₓS thin film before the treatment, and the optical band gap of the film is near to the optical band gap of 1.45 eV at which a solar ray can be converted into an electric energy the most efficiently by the treatment.

Incidentally, even in other material of a polycrystal CuGaSex, AgInSₓ, CuGaSeₓ thin film or the like, the same goes with the case of the CuInSeₓS_{y} thin film.

(7) A relationship between an atm and a chemical composition of a compound is as follows. A change in x+y (t) (x is a constant) in annealing of the compound XYZxSy(t) is represented as

y(t)=(2−x)−(2−x−y(0))exp(−kPt)

k: coefficient depending on substance
P: pressure.

Here, time t at which x+y≧1.95 becomes as t≧ln(0.05/2−x−y(0))kP by

2−(2−x−y(0))exp(−kPt)≧1.95.

Therefore, annealing may be carried out for time equal to or longer than −ln(0.05/2−x−y(0))/kP.

The Z atomic defect in the chalcopyrite compound thin film can be repaired by the sulfur atom. As a result, the optical band gap of the optical absorption film can be made to be near to an optimum value of a solar cell.

### BRIEF DESCRIPTION OF THE DRAWINGS

FIG. 1 is a view showing a fabrication device of a semiconductor thin film;

FIG. 2 is a diagram showing steps of treating a chalcopyrite thin film;

FIG. 3 is a diagram showing a pressure and a chemical composition of a film; and

FIG. 4 is a diagram showing a representative structure of a solar cell.

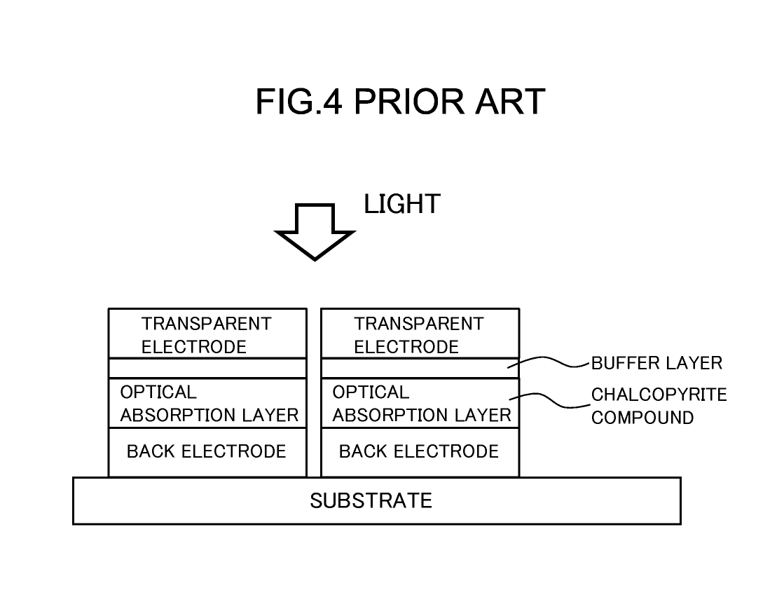

### DETAILED DESCRIPTION OF THE PREFERRED EMBODIMENTS

### First Embodiment

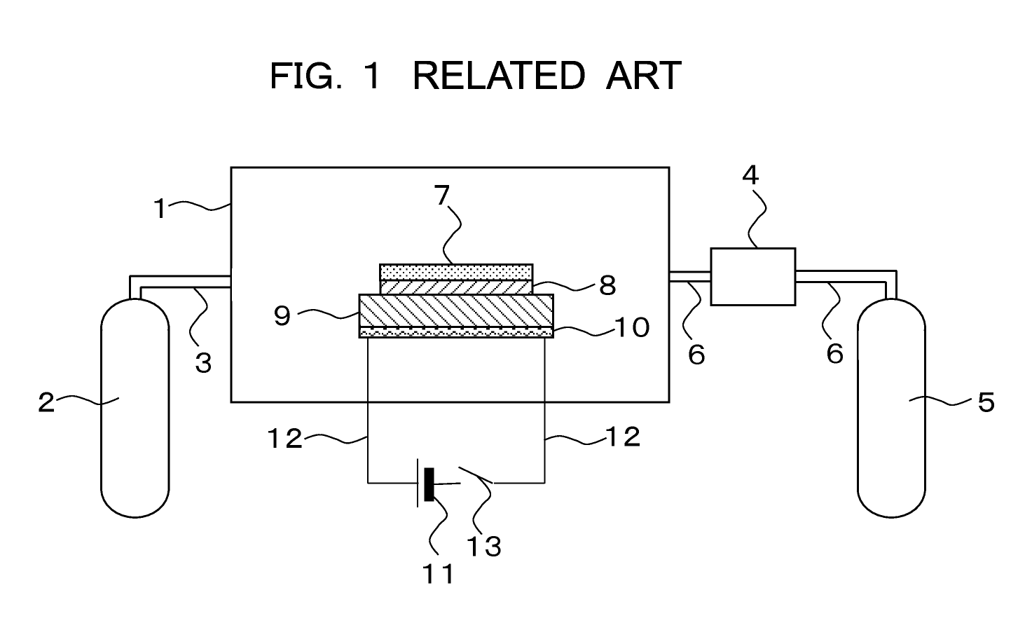

FIG. 1 shows an example of a fabrication device of a semiconductor thin film of the present invention. Numeral 1 designates a pressure chamber, numeral 2 designates a nitrogen gas bomb which is an inert gas source, numeral 3 designates a nitrogen gas pipe, numeral 4 designates a pressure pump which is a gas pressure device, numeral 5 designates an H₂S gas bomb which is a sulfur gas source, numeral 6 designates an H₂S gas pipe, numeral 7 designates a chalcopyrite thin film, numeral 8 designates a substrate, numeral 9 designates a thin film stage, numeral 10 designates a heater, numeral 11 designates an external power source, numeral 12 designates a power source cable, and numeral 13 designates an electric switch. The pressure chamber is connected to the pressure pump which is connected to the nitrogen gas bomb and the H₂S gas bomb, and is able to fill the nitrogen gas and the pressurized H₂S gas to inside of the chamber. The pressure chamber is made of a stainless steel and is able to enclose a gas at a pressure of from 10 atm to 100 atm at inside thereof. A surface of an inner wall of the pressure chamber is coated with gold. Thereby, the inner wall is prevented from being corroded in a case of filling the chamber with the H₂S gas. The thin film stage is installed in the pressure chamber, and a chalcopyrite compound thin film coated on the substrate is able to be arranged above the stage. A lower face of the thin film stage is arranged with an electric heater, and the electric heater is electrically connected to the power source installed outside the pressure chamber by the power source cable. The electric switch is between the electric heater and the power source, and temperatures of the thin film stage, the substrate arranged above the thin film stage, and the chalcopyrite compound thin film are allowed to be maintained to temperatures necessary for the treatment by making the switch ON/OFF.

Thus, the chalcopyrite thin film in the polycrystal state having the film thickness of 1 through 2 micrometers is formed.

### Second Embodiment

An explanation will be given of a method of carrying out a treatment of a fabrication method of a semiconductor thin film of the present invention by using the device of FIG. 1 by taking an example of a treatment of a CuInSe₂ thin film. The same goes also with the treatment of other chalcopyrite thin films.

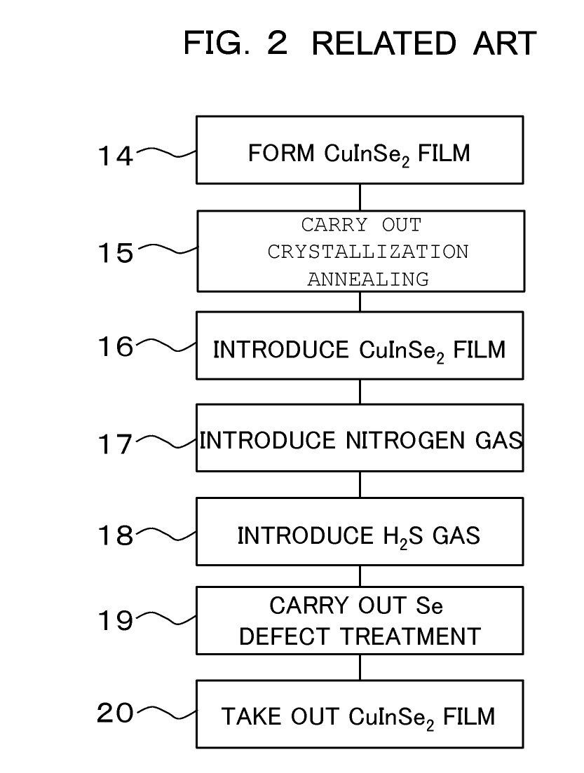

FIG. 2 is a flowchart in a case of treating the CuInSe₂ thin film by the present invention. Numeral 14 designates a film forming step of CuInSe₂, numeral 15 designates a crystallization treatment step of CuInSe₂, numeral 16 designates a step of introducing the CuInSe₂ thin film to the device of FIG. 1, numeral 17 designates a step of introducing an inert gas (here, nitrogen gas) to the pressure chamber 1, numeral 18 designates a step of introducing a sulfur gas to the pressure chamber 1, numeral 19 designates a step of treating an Se defect in the CuInSe₂ thin film, and numeral 20 designates a step of taking out the thin film from the device after finishing the treatment. In the drawing, numerals 14 and 15 designate treatment steps by the publicly known technology, and the steps of 16 through 20 designate treatment steps of the present invention.

At the step 14, the CuInSe₂ thin film is formed above the substrate by using ternary simultaneous vapor deposition method, a sputtering method, a roll-to-roll process which are publicly-known technologies, or the methods of Japanese Unexamined Patent Application Publication No. Hei 9(1997)-213977 and Japanese Unexamined Patent Application Publication (Translation of PCT Application) No. 2007-503708. At the step 15, the thin film is crystallized by treating the CuInSe₂ thin film at a condition of 500° C. or higher in a H₂Se gas atmosphere by using the publicly-known technologies. By the treatment of the step 15, the polycrystal CuInSe₂ thin film is obtained. At the step 16, the CuInSe₂ thin film fabricated above the substrate is arranged above the thin film stage 9 which is present in the pressure chamber. The CuInSe₂ thin film corresponds to numeral 7 of FIG. 1, and the substrate corresponds to numeral 8 of FIG. 1. At the step 17, the nitrogen gas is introduced into the pressure chamber by using the nitrogen bomb 2, and air in the chamber is substituted therefor. In this way, oxygen in air can be pushed out of the chamber by introducing the inert gas of the nitrogen or the like into the chamber, and the reaction between the sulfur gas which is introduced later and oxygen in air, for example, 2H₂S+3O₂→2H₂O+2SO₂ can be avoided.

At the step 18, the pressurized H₂S gas is introduced into the pressure chamber by using the pressure pump 4 and the H₂S gas bomb 5. The pressure of H₂S gas is 10 atm through 100 atm. At the step 19, electricity is supplied by using the power source cable 12 from the outside power source 11 to the electric heater, and the CuInSe₂ arranged above the thin film stage is subjected to a heating treatment. The temperature of the thin film is adjusted to be equal to or higher than 112° C. and less than 217° C. by using the electric switch 13. At the step 20, the CuInSe₂ thin film finished with the treatment is taken out of the pressure chamber 1.

### Third Embodiment

The CuInSe₂ thin film is formed on a glass substrate by using a publicly-known ternary simultaneous vapor deposition method. The film thickness is 1 μm, and the film is brought into a polycrystal state. The thin film is treated by using the device of FIG. 1 and the treatment scheme of FIG. 2. The film is treated for 1 hour by setting the substrate temperature at 120° C., and setting a pressure of H₂S gas to 1 atm, 10 atm, 50 atm, and 100 atm, and chemical compositions and optical band gaps of thin films provided by the treatment at respective pressures are investigated.

Table 1 shows the chemical compositions and the optical band gaps of the CuInSe₂ thin films as treated. The chemical compositions are indicated by coefficients of respective elements of the chemical formula of the film.

TABLE 1

| | Before | H₂S pressure | | | |
|---|---|---|---|---|---|
| | treatment | 1 atm | 10 atm | 50 atm | 100 atm |
| Cu | 0.8 | 0.8 | 0.8 | 0.8 | 0.8 |
| In | 1.14 | 1.14 | 1.14 | 1.14 | 1.14 |
| Se | 1.75 | 1.75 | 1.75 | 1.75 | 1.75 |
| S | 0 | 0.05 | 0.2 | 0.22 | 0.23 |
| Optical | 1.02 | 1.02 | 1.09 | 1.10 | 1.10 |
| band gap | | | | | |
| (eV) | | | | | |

Table 1 shows a chemical composition of the CuInSe₂ thin film before the treatment for comparison. The composition of the film before the treatment is Cu_{0.8}In_{1.14}Se_{1.75}, and the film includes a selenium atomic defect. When the film is treated under H₂S gas atmosphere at 1 atm by a method of the publicly-known technology, the Se defect at a vicinity of a surface of the crystal grain is repaired by the sulfur atom, and the composition of the film becomes Cu_{0.8}In_{1.14}Se_{1.75}S_{0.05}. However, the selenium atomic defect at the inner portion of the crystal grain remains unrepaired, and a sum of the coefficients of Se and S of the chemical formula of the film becomes 1.80.

On the other hand, in a case where the film is treated by setting the pressure of the H₂S gas to 10 atm, 50 atm, and 100 atm by the present invention, the sulfur atom is introduced also to the selenium atomic defect at the inner portion of the CuInSe₂ crystal grain, and the composition of the film becomes Cu_{0.8}In_{1.14}Se_{1.75}SeₓS_{y}, and a value of x+y is made to be equal to or more than 1.95 and equal to or less than 2. In this way, the CuInSeS film having few defects and is near to a stoichiometric composition can be obtained by repairing the selenium defect in the CuInSe₂ crystal by the sulfur atom by the present invention.

Incidentally, even when the CuInSe₂ film is treated, composition ratios of Cu, In, and Se remain unchanged by the present invention. In this way, only the selenium atom defect can be repaired by the sulfur atom without influencing the atoms.

When the CuInSe₂ film is treated, the sulfur atom is introduced to the selenium atom defect in the film, and therefore, the optical band gap of the film is increased by the present invention. The optical band gap of the CuInSe₂ treated by the method of the present invention is about 1.10 eV and is near to an optimum value 1.45 eV of the optical band gap of the solar cell in comparison with the optical band gap (1.02 eV) before the treatment. In this way, the optical band gap of the CuInSe₂ film can be brought near to an optimum value by the present invention.

### Fourth Embodiment

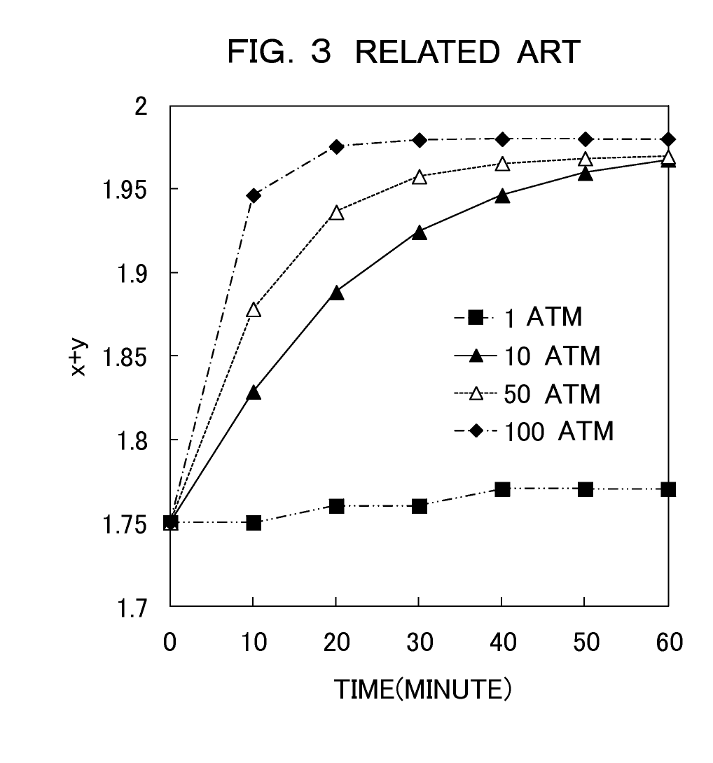

A polycrystal CuInSe₂ thin film having a film thickness of 1 μm is formed by using the publicly-known ternary simultaneous vapor deposition method and the thin film is treated by using the device of FIG. 1 and the treatment scheme of FIG. 2. The substrate temperature is set to 120° C., the pressure of the H₂S gas is set to 1 atm, 10 atm, 50 atm, and 100 atm, and changes over time of the chemical compositions of the thin film obtained by treatments at respective pressures are investigated. FIG. 3 shows changes over time of x+y values of the chemical compositions CuInSeₓS_{y} of the films at the respective pressures.

In a case where the film is treated under the H₂S gas atmosphere at 1 atm by using the publicly-known technology, a significant change over time is not observed in the x+y value. This is because the sulfur atom is introduced only to the selenium atomic defect near to the surface of the crystal grain, and the sulfur atom is not introduced to the selenium defect at the inner portion of the crystal grain.

On the other hand, in a case where the film is treated under the pressurized H₂S gas atmosphere by using the method of the present invention, the x+y value is increased along with time, and the x+y value becomes equal to or more than 1.95 after 1 hour even at any pressure of 10 atm, 50 atm, and 100 atm. It is found that, by the method of the present invention using the pressurized gas, the selenium atomic defect at the inner portion of the crystal grain is effectively repaired by the sulfur atom. As described in the first embodiment, even in a case where the treatment is carried out for 1 hour, the detachment of the selenium atom from the film is not observed.

Time until the x+y value becomes equal to or more than 1.95 is about 50 minutes in a case where the pressure of the H₂S gas is 10 atm, 30 minutes in a case of 50 atm, and about 10 minutes in a case of 100 atm. The higher the pressure of the H₂S gas, the shorter the time required for repairing the selenium atomic defect, and the effect of the present invention using the pressurized gas can be confirmed.

Actually, in a case of fabricating a solar cell which uses the CuInSe₂ thin film, it is preferable that the treatment time of the film is short in view of fabrication. The present invention can repair the selenium atomic defect in the film by the sulfur atom in comparatively short time, which is suitable for fabricating the CuInSe₂ solar cell.

### Fifth Embodiment

A CuGaSe₂ thin film is fabricated on a glass substrate by using the publicly-known ternary simultaneous vapor deposition method. The film thickness is 1.1 μm, and the film is brought into the polycrystal state. The thin film is treated by using the device of FIG. 1 and the treatment scheme of FIG. 2. The film is treated for 1 hour by setting the substrate temperature to 120° C., and the pressure of the H₂S gas to 1 atm, 10 atm, 50 atm, and 100 atm, and chemical compositions and the optical band gaps of the thin films obtained by the treatments under respective pressures are investigated.

Table 2 shows chemical compositions and optical band gaps of the CuGaSe₂ thin film as treated. The chemical compositions are indicated by coefficients of respective elements of chemical formula of the films.

TABLE 2

| | Before | H₂S pressure | | | |
|---|---|---|---|---|---|
| | treatment | 1 atm | 10 atm | 50 atm | 100 atm |
| Cu | 0.92 | 0.92 | 0.92 | 0.92 | 0.92 |
| In | 1.06 | 1.06 | 1.06 | 1.06 | 1.06 |
| Se | 1.70 | 1.70 | 1.70 | 1.70 | 1.70 |
| S | 0 | 0.10 | 0.25 | 0.27 | 0.28 |
| Optical | 1.65 | 1.66 | 1.78 | 1.78 | 1.79 |
| band gap | | | | | |
| (eV) | | | | | |

Table 2 shows a chemical composition of the CuGaSe₂ before treatment for comparison. The composition of the film before treatment is Cu_{0.92}Ga_{1.06}Se_{1.70}, and the film includes a selenium atomic defect. When the film is treated under the H₂S gas atmosphere at 1 atm by the method of the publicly-known technology, the selenium atomic defect at a vicinity of the surface of the crystal grain is repaired by the sulfur atom, and the composition of the film becomes Cu_{0.92}Ga_{1.06}Se_{1.70}S_{0.10}. However, the selenium atomic defect at the inner portion of the crystal grain remains unrepaired, and a sum of coefficients of Se and S of the chemical formula of the film becomes 1.80.

On the other hand, in a case of carrying out a treatment of the film by setting the pressure of the H₂S gas to 10 atm, 50 atm, and 100 atm by the present invention, the sulfur atom is introduced also to the selenium atomic defect at the inner portion of the crystal grain, the composition of the film becomes Cu_{0.92}Ga_{1.06}SeₓS_{y}, and the value of x+y can be made to be equal to or more than 1.95 and equal to or less than 2. In this way, the CuGaSeS thin film having few defects near to the stoichiometric composition can be obtained by repairing the selenium atomic defect in the CuGaSe₂ crystal by the sulfur atom by the present invention.

Incidentally, the composition ratios of Cu, Ga, and Se of the film remain unchanged even when the CuGaSe₂ film is treated by the present invention. In this way, only the selenium atomic defect can be repaired by the sulfur atom without influencing these atoms.

When the CuGaSe₂ film is treated by the present invention, the sulfur atom is introduced to the selenium atomic defect in the film, and therefore, the optical band gap of the film is increased. The optical band gap of the CuGaSe₂ film treated by the method of the present invention is about 1.78 eV, and is a value larger than an optical band gap (1.65 eV) of the film before treatment.

### Sixth Embodiment

An AgInSe₂ thin film is formed on a glass substrate by the publicly-known ternary simultaneous vapor deposition method. The film thickness is 2 μm, and the film is brought into a polycrystal state. The film is treated by using the device of FIG. 1 and the treatment scheme of FIG. 2. The film is treated for 1 hour by setting the substrate temperature to 120° C., and setting the pressure of the H₂S gas to 1 atm, 10 atm, 50 atm, and 100 atm, and chemical compositions and optical band gaps of the thin films obtained by the treatments at respective pressures are investigated.

Table 3 shows a chemical composition and an optical band gap of the AgInS₂ thin film as treated. The chemical composition is indicated by coefficients of respective elements in the chemical formula of the film.

TABLE 3

| | Before | H₂S pressure | | | |
|---|---|---|---|---|---|
| | treatment | 1 atm | 10 atm | 50 atm | 100 atm |
| Ag | 0.90 | 0.90 | 0.90 | 0.90 | 0.90 |
| In | 0.98 | 0.98 | 0.98 | 0.98 | 0.98 |
| S | 1.50 | 1.65 | 1.96 | 1.97 | 1.99 |
| Optical | 1.79 | 1.81 | 1.83 | 1.84 | 1.85 |
| band gap | | | | | |
| (eV) | | | | | |

Table 3 shows a chemical composition of an AgInS₂ thin film before treatment for comparison. A composition of the film before treatment is Ag_{0.90}In_{0.98}S_{1.50}, and the film includes the sulfur atom defect. When the film is treated under the H₂S gas atmosphere at 1 atm by the publicly-known technologies, the sulfur atomic defect at a vicinity of the surface of the crystal grain is repaired by the sulfur atom, and the composition of the film becomes Ag_{0.90}In_{0.98}S_{1.65}. The sulfur atomic defect at the inner portion of the crystal grain remains unrepaired, and the coefficient S of the chemical formula of the film becomes 1.65.

On the other hand, in a case of treating the film by setting the pressure of the H₂S gas to 10 atm, 50 atm, and 100 atm by the present invention, the sulfur atom is introduced also to the sulfur atom defect at the inner portion of the crystal grain, a composition of the film becomes Ag_{0.90}In_{0.98}S_{x+y}, and the value of x+y can be made to be equal to or more than 1.95 and equal to or less than 2. In this way, the sulfur atomic defect in the AgInS₂ crystal can be repaired by the sulfur atom by the present invention.

Incidentally, even when the AgInS₂ film is treated, composition ratios of Ag and In are not changed and it is not observed that the composition ratio of S is reduced by the present invention. In this way, according to the present invention, only the sulfur atomic defect in the film can be repaired by the sulfur atom without influencing the atom which is present in the film before treatment.

When the AgInS₂ film is treated by the present invention, the sulfur atom is introduced into the sulfur atom defect in the film, and therefore, the optical band gap of the film is increased. The optical band gap of the AgInS₂ film treated by the method of the present invention is 1.83 through 1.85 eV, and is a value larger than the optical band gap (1.79 eV) of the film before treatment. The optical band gap of the treated film becomes a value extremely near to 1.87 eV which is an optical band gap of an AgInS₂ single crystal.

In this way, the AgInS₂ film with an electronic property near to that of the stoichiometric AgInS₂ is obtained by the present invention.

### Seventh Embodiment

A CuGaTe₂ thin film is formed on a glass substrate by using the publicly-known ternary simultaneous vapor deposition method. The film thickness is 2 μm, and the film is brought into a polycrystal state. The thin film is treated by using the device of FIG. 1 and the treatment scheme of FIG. 2. The film is treated for 1 hour by setting the substrate temperature to 120° C., and setting the pressure of the H₂S gas to 1 atm, 10 atm, 50 atm, and 100 atm, and chemical compositions and optical band gaps of the thin films obtained by the treatments at the respective pressures are investigated.

Table 4 shows chemical compositions and optical band gaps of the CuGaTe₂ thin film as treated. The chemical compositions are indicated by coefficients of the respective elements of the chemical formula of the film.

TABLE 4

| | Before | H₂S pressure | | | |
|---|---|---|---|---|---|
| | treatment | 1 atm | 10 atm | 50 atm | 100 atm |
| Cu | 0.89 | 0.89 | 0.89 | 0.89 | 0.89 |
| Ga | 1.04 | 1.04 | 1.04 | 1.04 | 1.04 |
| Te | 1.65 | 1.65 | 1.65 | 1.65 | 1.65 |
| S | 0 | 0.12 | 0.31 | 0.32 | 0.33 |
| Optical | 1.22 | 1.31 | 1.42 | 1.42 | 1.43 |
| band gap | | | | | |
| (eV) | | | | | |

Table 4 shows the chemical composition of the AgInS₂ thin film before treatment for comparison. The composition of the film of the treatment is

Cu_{0.89}Ga_{11.04}Te_{1.65}, and the film includes the sulfur atomic defect. When the film is treated under the H₂S gas atmosphere at 1 atm by the method of the publicly-known technology, a tellurium atomic defect at a vicinity of the crystal grain surface is repaired by the sulfur atom, and the composition of the film becomes Cu_{0.89}Ga_{1.04}Te_{1.65}S_{0.12}.

On the other hand, in a case where the film is treated by setting a pressure of the H₂S gas to 10 atm, 50 atm, and 100 atm by the present invention, the sulfur atom is introduced also to the tellurium atomic defect at the inner portion of the crystal grain, the composition of the film becomes Cu0.89Ga1.04Sx+y, and a value of x+y can be made to be equal to or more than 1.95 and equal to or less than 2. In this way, the tellurium atomic defect in the CuGaTe₂ crystal can be repaired by the sulfur atom. A gas including toxic Te may not be used by repairing the Te atomic defect by the gas including S.

Incidentally, composition ratios of Cu, Ga, and Te of the film remain unchanged even when the CuGaTe₂ film is treated by the present invention. In this way, according to the present invention, only the tellurium atomic defect in the film can be repaired by the sulfur atom without influencing atoms in the film before treatment.

When the CuGaTe₂ film is treated by the present invention, the sulfur atom is introduced to the tellurium atomic defect in the film, and therefore, the optical band gap of the film is increased. The CuGaTe₂ film treated by the method of the present invention has an optical band gap larger than that of the CuGaTe₂ film before treatment, and a value thereof is 1.42 through 1.43 eV. The optical band gap is extremely near to the optical band gap of 1.45 eV which can convert a solar ray into electric energy most efficiently.

In this way, according to the present invention, the CuGaTe₂ thin film having an ideal optical band gap can be obtained as the optical absorption layer of the solar cell by the present invention. The CuGaTe₂ thin film treated by the present invention has an advantage that In which is a premium grade element is not included, and is excellent in view of an element strategy.

### Eighth Embodiment

A CuAlSe₂ thin film is formed on a glass substrate by using the publicly-known ternary simultaneous vapor deposition method. The film thickness is 2 μm, and the film is in a polycrystal state. The thin film is treated by using the device of FIG. 1 and the treatment scheme of FIG. 2. The film is treated for 1 hour by setting the substrate temperature to 120° C., and setting the pressure of the H₂S gas to 1 atm, 10 atm, 50 atm, and 100 atm, and chemical compositions and optical band gaps of the thin films provided by the treatments under the respective pressures are investigated.

Table 5 shows chemical compositions and optical band gaps of the CuGaTe₂ thin films as treated. The chemical composition is indicated by coefficients of respective elements of the chemical formula of the film.

TABLE 5

| | Before | H₂S pressure | | | |
|---|---|---|---|---|---|
| | treatment | 1 atm | 10 atm | 50 atm | 100 atm |
| Cu | 0.81 | 0.81 | 0.81 | 0.81 | 0.81 |
| Al | 1.01 | 1.01 | 1.01 | 1.01 | 1.01 |
| Se | 1.73 | 1.74 | 1.74 | 1.74 | 1.74 |
| S | 0 | 0.15 | 0.23 | 0.24 | 0.24 |
| Optical | 2.65 | 2.73 | 2.76 | 2.77 | 2.77 |
| band gap | | | | | |
| (eV) | | | | | |

The table shows a chemical composition of the CuAlSe₂ thin film before treatment for comparison. The composition of the film of the treatment is Cu_{0.81}Al_{1.04}Se_{1.73}, and the film includes the sulfur atomic defect. When the film is treated under the H₂S gas atmosphere at 1 atm by the method of the publicly-known technologies, the selenium atomic defect at a vicinity of the surface of the crystal grain is repaired by the sulfur atom, and the composition of the film becomes Cu_{0.81}Al_{1.04}Se_{1.73}S_{0.15}.

On the other hand, in a case where the film is treated by setting the pressure of the H₂S to 10 atm, 50 atm, and 100 atm by the present invention, the sulfur atom is introduced into the tellurium atomic defect at the inner portion of the crystal grain, the composition of the film becomes Cu_{0.81}Al_{1.04}SeₓS_{y}, and a value of x+y can be made to be equal to or more than 1.95 and equal to or less than 2. In this way, the sulfur atomic defect in the CuAlSe₂ crystal can be repaired by the sulfur atom.

Incidentally, even when the CuAlSe₂ film is treated by the present invention, composition ratios of Cu, Al, and Se of the film remain unchanged. In this way, the present invention can repair only the selenium atomic defect in the film by the sulfur atom without influencing on the atom which exists in the film before the treatment.

When the CuAlSe₂ film is treated by the present invention, the sulfur atom is introduced to the selenium atomic defect in the film, and therefore, optical band gap of the film is increased. The CuAlSe₂ film treated by the method of the present invention has the optical band gap which is larger than that of the CuAlSe₂ film before treatment, and the value is from 2.76 through 2.77 eV.

As shown in the above embodiments, the chalcopyrite compound thin film defect can effectively be repaired by the sulfur atom by the present invention. Incidentally, although according to the embodiments described above, examples of repairing the selenium and the sulfur atomic defects in CuInSe₂, CuGaSe₂, AgInS₂ and CuAlSe₂ thin films and repairing the tellurium atomic defect in the CuGaTe₂ thin film have been described, a similar effect is achieved also for other chalcopyrite compound thin films having the different composition.

Incidentally, although according to the embodiments described above, the explanation has been given of the ternary elements compound, a similar effect is achieved also for four-element compounds of, for example, CuInAlSe₂ including In, Al as Y.

Also, although according to the explanation described above, the pressure of the pressurized sulfur gas is made to be equal to or more than 10 atm and equal to or less than 100 atm, a similar effect is achieved even when the pressure of the gas is made to be equal to or more than 2 atm and less than 10 atm. However, in this case, an annealing time period which is necessary for obtaining a chalcopyrite compound thin film having a prescribed chemical composition is prolonged. On the other hand, a chalcopyrite compound thin film having a prescribed chemical composition can be obtained by annealing for comparatively short time by making the pressure of the pressurized sulfur gas equal to or more than 10 atm and equal to or less than 100 atm.

### REFERENCE SIGNS LIST

1 . . . pressure chamber,
2 . . . inert gas source,
3 . . . nitrogen gas pipe,
4 . . . gas pressure device,
5 . . . sulfur gas source,
6 . . . sulfur gas pipe,
7 . . . chalcopyrite thin film,
8 . . . substrate,
9 . . . thin film stage,
10 . . . electric heater,
11 . . . external power source,
12 . . . power source cable,
13 . . . electric switch,
14 . . . film forming step of CuInSe₂,
15 . . . crystallization treatment step of CuInSe₂,
16 . . . step of introducing the CuInSe₂ thin film to the device of FIG. 1,
17 . . . step of introducing an inert gas to the pressure chamber 1,
18 . . . step of introducing a sulfur gas to the pressure chamber 1,
19 . . . step of treating an Se defect in the CuInSe₂ thin film,
20 . . . step of taking out the thin film from the device after finishing the treatment.

What is claimed is:

1. A fabrication method of a semiconductor film comprising:
a step of forming a chalcopyrite compound film on a substrate; and
a step of subjecting the formed chalcopyrite compound film to an annealing treatment in a gas atmosphere including sulfur under a pressurized condition.

2. The fabrication method of a semiconductor film according to claim 1, wherein a chemical formula of the chalcopyrite compound is designated by XYZ₂, X is silver or copper, Y is gallium, indium, or aluminum, and Z is sulfur, selenium, or tellurium.

3. The fabrication method of a semiconductor film according to claim 1, wherein the pressurized condition is equal to or more than 2 atm and equal to or less than 100 atm.

4. The fabrication method of a semiconductor film according to claim 1, wherein the pressurized condition is equal to or more than 10 atm and equal to or less than 100 atm.

5. The fabrication method of a semiconductor film according to claim 1,
wherein the chalcopyrite compound includes selenium or sulfur; and
wherein an annealing temperature is lower than 217° C. and higher than 112° C.

6. The fabrication method of a semiconductor film according to claim 1,
wherein the chalcopyrite compound includes tellurium; and
wherein the annealing temperature is lower than 449° C. and higher than 112° C.

7. The fabrication method of a semiconductor film according to claim 1, wherein the gas including sulfur is a hydrogen sulfide gas.

8. The fabrication method of a semiconductor film according to claim 1, wherein when a chemical formula of the chalcopyrite compound after subjecting to the annealing treatment is designated by XYZxSy(t) (t is time), and a pressure under the pressurized condition is designated by P, the annealing treatment is carried out for a time period equal to or longer than −ln(0.05/2−x−y(0))/kP (where notation k designates a coefficient depending on a substance).

9. The fabrication method of a semiconductor film according to claim 1, wherein the annealing treatment is carried out for 10 minutes or longer.

10. The fabrication method of a semiconductor film according to claim 1, further comprising:
a step of carrying out crystallization annealing of the chalcopyrite compound film; and
a step of introducing an inert gas into an annealing device;
after the step of forming the chalcopyrite compound film and before the step of subjecting the formed chalcopyrite compound film to the annealing treatment.

11. A solar cell comprising a substrate and having a chalcopyrite compound as an optical absorption film;
wherein the chalcopyrite compound is designated by XYZₓS_{y} (X is silver or copper, Y is gallium, indium, or aluminum, Z is sulfur, selenium, or tellurium, S is sulfur) and a value of x+y is equal to or more than 1.95 and equal to or less than 2.

12. The solar cell according to claim 11, wherein the chalcopyrite compound includes four or more elements.

13. A chalcopyrite compound which is a chalcopyrite compound designated by XYZxSy (X is sliver or copper, Y is gallium, indium, or aluminum, Z is sulfur, selenium, or tellurium, S is sulfur), wherein a value of x+y is equal to or more than 1.95 and equal to or less than 2.
